(19) United States
(12) Patent Application Publication
(10) Pub. No.: US 2005/0035366 A1
(43) Pub. Date: Feb. 17, 2005

(54) Light emitting diode

(75) Inventor: Sadato Imai, Yamanashi (JP)

Correspondence Address: BROWDY AND NEIMARK, P.L.L.C.;624 NINTH STREET, NW, SUITE 300, WASHINGTON, DC, 20001-5303, US

(73) Assignee: Citizen Electronics Co., Ltd., Yamanashi (JP)

(21) Appl. No.: 10/915,422

(22) Filed: Aug. 11, 2004

(30) Foreign Application Priority Data
Aug. 13, 2003 (JP) 2003-207530

(51) Int. Cl. H01L 33/00

(52) U.S. Cl. 257/100

(57) ABSTRACT

A light emitting diode, comprising a circuit substrate, an LED chip, a heat radiating mechanism provided on said circuit substrate and supporting said LED chip to receive heat from the LED chip and radiate the heat, and a sealing body provided on said circuit substrate to cover said LED chip

### CROSS REFERENCE TO THE RELATED APPLICATION

The application claims the priority benefit of Japanese Patent Application No. 2003-207530, filed on Aug. 13, 2003, the entire descriptions of which are incorporated herein by reference.

### BACKGROUND OF THE INVENTION

1. Field of the Invention

The present invention relates to a light emitting diode used in commercial devices such as personal computers, printers, PDAs (Personal Digital Assistants), facsimiles, pagers and mobile phones, more specifically to a light emitting diode having an excellent heat release effect.

2. Description of Related Art

Conventionally, in a surface-mounted light emitting diode provided toward electronic devices pursuing slimness and miniaturization, there has been known a structure in which an LED chip is mounted on electrode patterns formed on an upper surface of a substrate of glass epoxy and a transparent resin is provided on the substrate to seal the LED chip (see Japanese Patent Laid-Open 2002-280614, p2, FIG. 4).

FIG. 3 illustrates a light emitting diode 30 as disclosed in the patent document.

The light emitting diode 30 has a structure in which a pair of upper surface electrodes 32a, 32b and lower surface electrodes 33a, 33b integrally plated are patterned on a circuit substrate 31 to surround a part of an upper surface and a lower surface of the circuit substrate 31 which is made of an insulative material such as a glass epoxy resin, an LED chip 34 is fixed on a part of the upper surface electrode 32a by a transparent adhesive and is electrically connected with the upper surface electrodes 32a and 32b by bonding wires 35 and 36, and the LED chip 34 and bonding wires 35 and 36 are sealed by a sealing body 37 made of a transparent resin.

When using, the light emitting diode 30 is surface-mounted on a printed board 38 by loading the light emitting diode on an upper surface of the printed board and electrically fixing the lower surface electrodes 33a and 33b to printed wirings on the printed board 38 by soldering 39.

However, if the aforementioned light emitting diode is used in an application of high brightness and high output, there are the following problems about heat release from the LED chip.

FIG. 4 illustrates a relationship between a driving current flowing in the LED chip and brightness thereof. FIG. 4 (a) shows a case having an efficient heat release from the LED chip, FIG. 4 (b) shows a case having an inefficient heat release from the LED chip. The LED chip has a relationship that the driving current and the brightness are generally proportional until arriving a constant operation region, the driving current is increased in order to obtain high brightness.

However, when the driving current is increased, power loss of the LED chip is increased in proportion to the increment of the driving current. In other words, most of energy is converted into heat which raises the temperature of the LED chip higher. Because the material of the circuit substrate, on which the LED chip is mounted through the plated electrode patterns is the glass epoxy resin, the heat conductivity of the material is very small. Therefore, heat release from the heated LED chip is only performed through the plated surfaces of the electrode patterns, and therefore heat release is not almost performed. As a result, the temperature of the LED chip is not reduced.

If the temperature of an LED chip is lower, the light emitting efficiency, in other words, current-light conversion efficiency is higher. Therefore, the LED chip is heated, there is a problem that the light emitting brightness is lowered. Moreover, an operating life of the LED chip becomes shorter, when it is operated in a higher temperature. Furthermore, there is a problem that the transparent sealing body sealing the LED chip changes in color due to heat, and transparency thereof is decreased. In addition, there is a problem that the LED chip tends to have a shorter operating life and less reliability when used in the application of high output and high brightness.

### SUMMARY OF THE INVENTION

The present invention has been made in view of the problems of the prior art, an object thereof is to provide a compact, thin and inexpensive light emitting diode having excellent characteristics of heat release.

To attain the above object, a light emitting diode in an aspect of the present invention comprises a circuit substrate, an LED chip, a heat radiating mechanism provided on the circuit substrate and supporting the LED chip to receive heat from the LED chip and radiate the heat, and a sealing body provided on the circuit substrate to cover the LED chip.

The heat generated in the LED chip is released through the heat radiating mechanism to outside of the circuit substrate.

### BRIEF DESCRIPTION OF THE DRAWINGS

FIG. 1 is a sectional view showing a first embodiment of a light emitting diode according to the present invention.

FIG. 2 is a sectional view showing a second embodiment of the light emitting diode according to the present invention.

FIG. 3 is a sectional view showing a conventional light emitting diode.

FIG. 4 is a graph showing a relationship between current and brightness, comparing a case having an efficient heat release and a case having an inefficient heat release from an LED chip.

### DETAILED DESCRIPTION OF THE PREFERRED EMBODIMENTS

Preferred embodiments of a light emitting diode according to the present invention will be explained with reference to the accompanying drawings below.

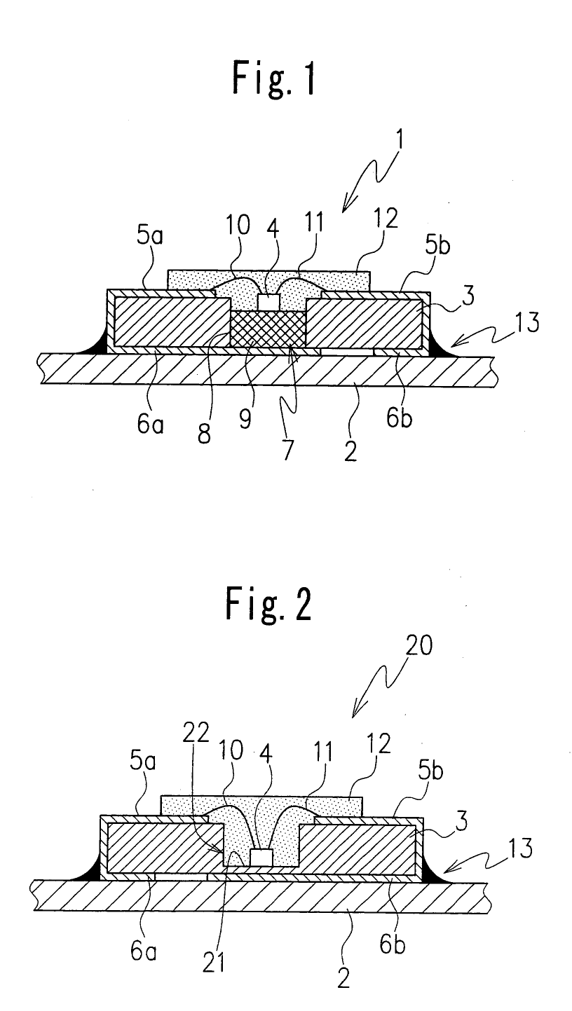

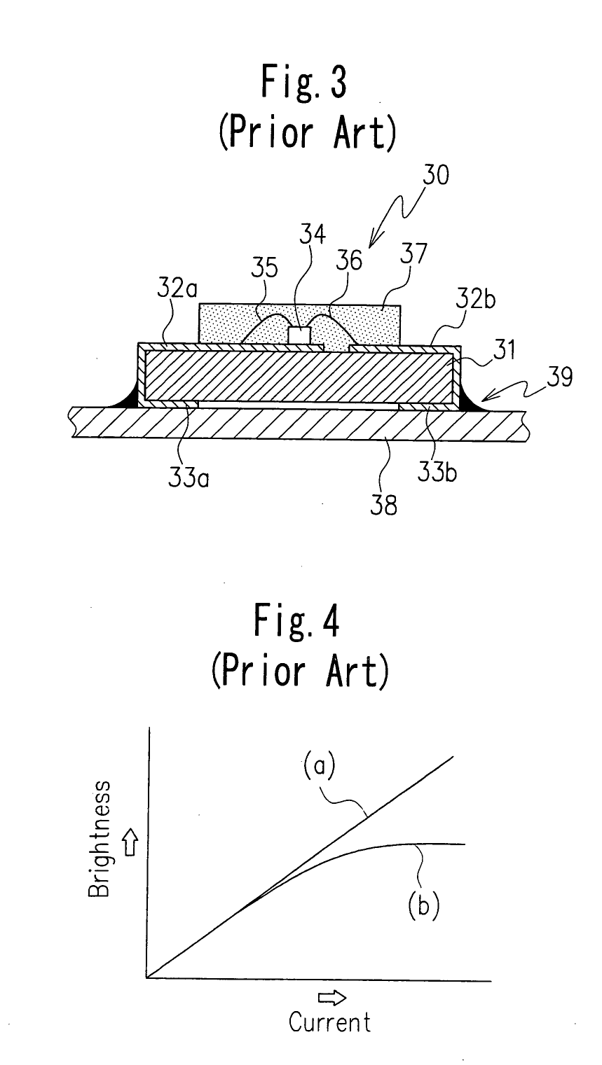

FIG. 1 illustrates the light emitting diode 1 in a first embodiment of the present invention.

The light emitting diode 1 comprises an LED chip 4, an insulative circuit substrate 3 in which the LED chip 4 is disposed and a printed board 2. The insulative circuit substrate 3 is made of glass epoxy resin, silicone or the like.

A pair of integrally formed upper and lower surface electrodes 5a, 6a and 5b, 6b are provided on the circuit substrate 3.

The circuit substrate 3 is provided with a heat radiating mechanism 7. The heat radiating mechanism 7 includes a heat radiating member 9 disposed in a storage part 8 formed in a generally central portion of the circuit substrate 3 in the embodiment shown in FIG. 1. The storage part 8 comprises a through hole formed in the circuit substrate 3, for example. When the heat radiating member 9 is inserted in the storage part 8, the heat radiating member 9 is disposed to contact through the lower electrode 6a with a surface of the printed board 2 contacting with a lower surface of the circuit substrate 3, and fixed by an appropriate fixing means such as an ultrasonic welding, brazing with a preferably same kind of metal of the heat radiating member 9, or the like, which is not shown.

The LED chip 4 is fixed on an upper surface of the heat radiating member 9 by a transparent adhesive or the like.

The heat radiating member 9 is preferably made of a material with good heat conductivity, for example, Al or Cu material.

The LED chip 4 is electrically connected with the upper surface electrodes 5a and 5b by wires 10 and 11, using a wire bonding technology.

The LED chip 4 and the wires 10, 11 are sealed by a sealing body 12. The sealing body 12 is made of a transparent resin attached to the circuit substrate 3 to cover the LED chip 4 and the wires 10, 11. The sealing body 12 also works for always pressing the heat radiating member 9 against the printed board 2 to prevent the heat radiating member 9 from separating from the printed board 2 due to vibration or the like.

The above light emitting diode 1 is surface-mounted in such a manner that the circuit substrate 3 is disposed on the printed board 2, and a printed wiring (not shown) of the printed board 2 and the lower surface electrodes 6a, 6b of the circuit substrate 3 are electrically connected by, for example, soldering 13.

In addition, if the upper surface of the heat radiating member 9 mounting the LED chip 4 has a level lower than that of the circuit substrate 3, it is possible to lower a height of the sealing body 12, accordingly, to lower the entire height of the light emitting diode. FIG. 1 shows that the plated electrode 6a is extending to the heat radiating member 9, however, the heat radiating member 9 directly disposed on the printed board 2 is also available.

Next, an operation of the light emitting diode as described above will be explained.

When the light emitting diode 1 is used in an application for high brightness and high output, a driving current passing through the LED chip 4 is increased in order to acquire the high brightness, and the LED chip 4 is heated to a considerably high temperature. Heat generated in the LED chip 4 is transmitted to the heat radiating member 9 and then is released from the heat radiating member 9 to the printed board 2 through the lower surface electrodes 6a and 6b made of a material having high conductivity such as a copper foil, thereby the temperature of the LED chip decreases rapidly, as a result, rise in temperature of the LED chip 4 can be stopped and it is avoided that efficiency of light emission decreases.

It is also avoided that transparency of the sealing body 12 sealing the LED chip 4 decreases due to heat causing color changes of the sealing body 12.

FIG. 2 illustrates a light emitting diode 20 in a second embodiment of the present invention.

In the second embodiment, the same numerals are attached to the similar parts as in the first embodiment.

The second embodiment differs from the first embodiment in that the heat radiating member 9 disposed in a storage part 8 of the through-hole is not used.

A recess 21 is formed by providing a concave portion 22, remaining a part of the circuit substrate 8 made of the insulative glass epoxy resin as thin as possible at an innermost part of the recess 21. The LED chip 4 is inserted in the concave portion 22 and mounted on the innermost of the recess 21. The LED chip 4 is fixed on the innermost of the recess 21 by a transparent adhesive or the like, similarly as the first embodiment as described above.

Similarly as the first embodiment, the sealing body 12 made of the transparent resin is provided in the concave portion 22 and on the upper surface of the circuit substrate 3 to cover the LED chip 4.

The light emitting diode 20 is also surface-mounted on the printed board 2 in the same manner as the first embodiment.

The plated electrode 6b is extending to the underside of the innermost part of the recess 21 and works as a heat radiating member 9 in the first embodiment. The heat generated in the LED chip 4 is released to the printed board 2 through the thinned part of the circuit substrate 3 and the extended substrate 6b.

Consequently, increment of the temperature of the LED chip 4 can be prevented, the light emitting efficiency does not decrease. Because the temperature of the LED chip 4 does not elevate, the transparency of the sealing body 12 does not decrease. Because the LED chip 4 is contained in the concave portion 22, the light emitting diode can be thinned.

In the first and second embodiments, because the heat radiating member 9, the extending electrode 6a or 6b made of a material having a good heat conductivity is contacted with the surface of the printed board, the heat of the LED chip 4 can be very efficiently emitted to the printed board 2.

As described above, the present invention makes it possible to provide a compact, thin and inexpensive light emitting diode, in which the light emitting efficiency and operating life of the LED chip are not reduced. Even if the driving current of the LED chip is increased, lowering the transparency of the sealing body can be prevented by releasing heat generated in the LED chip through the heat radiating mechanism to the printed board.

Although the preferred embodiments of the present invention have been described, the present invention is not limited to the embodiments, various changes and modifications can be made to the embodiments.

1. A light emitting diode, comprising:
a circuit substrate;
an LED chip;
a heat radiating mechanism provided on said circuit substrate and supporting said LED chip to receive heat from the LED chip and radiate the heat; and
a sealing body provided on said circuit substrate to seal said LED chip.

2. The light emitting diode according to claim 1,
wherein said heat radiating mechanism comprises a heat radiating member housed in a storage part formed in the circuit substrate, and
wherein the LED chip is mounted on an upper surface of the heat radiating member.

3. The light emitting diode according to claim 1,
wherein said heat radiating mechanism comprises an extended lower surface electrode on which said LED chip is mounted.

4. The light emitting diode according to claim 2,
wherein said storage part comprises a through hole formed in the circuit substrate.

5. The light emitting diode according to claim 2,
wherein the heat radiating member is made of Al or Cu.

6. The light emitting diode according to claim 1,
wherein said light emitting diode is fixed so that the circuit substrate is mounted on a printed board, and
wherein said heat radiating mechanism is configured to release heat of the LED chip to the printed board.
